(19) United States
(12) Patent Application Publication
(10) Pub. No.: US 2025/0098202 A1
(43) Pub. Date: Mar. 20, 2025

(54) LOW-RESISTANCE ELECTRON TRANSPORT IN SOLIDS

(71) Applicant: Jürgen ANDRÄ, CORENC (FR)

(72) Inventor: Jürgen ANDRÄ, CORENC (FR)

(73) Assignee: Jürgen ANDRÄ, CORENC (FR)

(21) Appl. No.: 18/964,635

(22) Filed: Dec. 1, 2024

Related U.S. Application Data
(63) Continuation of application No. PCT/EP2023/063426, filed on May 18, 2023.

(30) Foreign Application Priority Data
Jun. 1, 2022 (EP) 22020256.8

(51) Int. Cl. H01L 29/778

(52) U.S. Cl. CPC H10D 30/475

(57) ABSTRACT

Voltage-controlled, resistance-free electric current conduction in 2-dimensional electron gases (2DEG) and its technical application at temperatures (T) up to above room temperature can be achieved by electrons with energies E<(E_{F}-k_{B}T) (E_{F}=Fermi energy, k=Boltzmann constant) of a completely filled conduction band of a 2DEG which are exposed to a magnetic field B_{z} in the z-direction and an electric field E_{y} in the y-direction, which forces all of them to move in cyclotron motion in the x-y-plane with a common drift velocity v_{Dx} in the x-direction. The resulting electric drift current Jₓ has no resistance, as the electrons involved can neither be accelerated in a sole electric field nor disturbed by scattering from defects, impurities or phonons, as all possible final states of these processes are occupied by other electrons in the 2DEG. Minor losses only occur due to J_{y} currents of the normally conducting electrons of the 2DEG with energies between E=E_{F}±k_{B}T which are necessary for the generation of the E_{y} field in the 2DEG.

### CROSS-REFERENCE TO RELATED APPLICATIONS

This application is a continuation of copending International Application No. PCT/EP2023/063426, filed May 18, 2023, which is incorporated herein by reference in its entirety, and additionally claims priority from European Application No. EP 22020256.8, filed Jun. 1, 2022, which is also incorporated herein by reference in its entirety.

Conventional solid-state electronic components and electric conductors suffer from electric and thermal losses due to electric resistances. The present invention relates to the reduction of these electric resistances and thus of these losses of electronic conduction in solids and the generation of low-loss electric currents in solids at temperatures up to above room temperature.

### BACKGROUND OF THE INVENTION

Electric conduction by electrons in a filled conduction band of a solid (metal) is known. Electrons with energies in the range of the thermally softened Fermi edge E_{F}±kT (k=Boltzmann constant, T=temperature) are accelerated in the applied electric field Eₓ in the x-direction to excited, previously unoccupied energy states. This electron acceleration is slowed down by scattering from ions, crystal defects, impurities or phonons, which can be observed as electric resistance. All electrons in the conduction band with energies in the range from the ground state E_{1z} to approximately E_{F}−kT cannot participate in electric conduction, as all final states of an acceleration process are occupied for these electrons.

The latter restriction can be removed by applying a magnetic field B_{z} in the z direction, since an electron performs a cyclotron motion in the x-y plane with the area requirement of S=h/(eB_{z}) (see Ref. [1]) and the repetition frequency v=eB_{z}/(2 πmₑ*), where e is its electric charge, h is Planck's quantum of action and mₑ* is its effective mass in the corresponding material. If this electron is exposed to an additional electric field E_{y} in the y-direction, it undergoes a cyclotron drift movement in the x-direction with the drift speed v_{Dx}=U_{y}/B_{z}. The frequency and the cyclotron drift velocity are independent of the electron's energy.

In an electricity conducting solid, electrons in the above sense can only perform a cyclotron drift movement if their mobility μ=eτ/mₑ* [m²/Vs] (e=electron charge, τ=average free flight time, mₑ*=reduced electron mass) becomes large enough to allow the electrons to perform several cyclotron periods P=1/v in the average free flight time τ. The estimated condition τ≥10 P then yields μ≥20 π/B_{z} [m²/Vs], where B_{z} is to be used in the unit Tesla [Vs/m²]. In 3-dimensional solids, this condition up to now is not met for magnetic fields B_{z}≤1 Tesla and room temperature. In 2-dimensional electron gases (2DEG) such as in industrially used HEMTs (High Electron Mobility Transistor) [2] or MOSFETs (Metal Oxide Semiconductor Field Effect Tranistor, see FIG. 10.36 in Ref. [1]), however, this condition can be fulfilled. Therefore, from here on, the general validity for all solids of the application is given up the application only focuses on 2DEG.

It is known that the electric conduction of a 2DEG is only achieved by electrons with energies close to the softened Fermi edge E=E_{F}±kT (see p.296 of Ref. [1]) (k=Boltzmann constant, T=temperature in Kelvin, E_{F}=Fermi energy). These electrons are accelerated into excited, previously unoccupied energy states by applying an electric field Eₓ in the x-direction. This electron acceleration is slowed down by elastic scattering on ions, crystal defects, impurities or by inelastic scattering on phonons, which can be observed as electric resistance and limited mobility μ.

All energetic states of the 2DEG conduction band are occupied from the ground state E_{1z} to the softened Fermi edge E_{F}±kT with constant energy density D(E). The electrons with energies E_{1z}≤E≤E_{F}−kT are excluded from electric conduction as all final states of an acceleration process are occupied for these electrons. The above-mentioned scattering processes cannot influence these noble electrons either, as the final states of all these scattering processes are also occupied (see FIG. 7.11 of Ref. [1]). This is the physical cause of the resistance-less currents observed in the quantum Hall effects, which were first physically explained in the introduction to Ref. [3].

### SUMMARY

An embodiment may have a low-resistance to resistance-less electrical conductance at temperatures up to above room temperature, wherein a fraction of the electrons of high mobility μ>20 π/B_{z} m²/Vs located in the conduction band of a solid cannot be accelerated by an electric field and cannot be scattered by ions, defects, impurities or phonons, since all possible final states of these processes are occupied for these electrons, so that this fraction of electrons when exposed to crossed magnetic B_{z}-fields in the z-direction and electric E_{y}-fields in the y-direction provide a resistance-free cyclotron drift current in the x-direction, which reduces the overall electrical resistance of this solid.

The task of the invention is to utilize these noble electrons with energies E_{1z}≤E≤E_{F}−kT for electric current conduction without impairing their special properties and thus to generate a loss-free electron current. The prerequisites for this are a) the generation of an 2DEG and b) a method for imposing a drift velocity v_{D} on the noble electrons of the 2DEG.

Ad a) A typical 2DEG is confined in a potential well of energetic depth E₀, length Lₓ, width L_{y}<Lₓ, and height L_{z}. L_{z} is made so small that quantum mechanically only the ground state E_{1z}>E₀ can exist. In the following, such a potential well is referred to as a quantum well (QW). With a constant electron energy density D(E)=Lₓ·L_{y}·4·π·m*/h² (see Eq. 7.1.22 in Ref. [1] with h=Planck's quantum of action and m*=reduced mass of the electrons), the 2DEG fills all energy states of this QW from E_{1z} to E_{F}±kT. The number of electrons Nₑ in the 2DEG results in Nₑ=D(E)·(E_{F}−E_{F1z})=D(E)·E_{F1z}. The z-wave function of the E_{1z} state has exponential tails into the walls at z=0 and z=L_{z}. All other energy states of the 2DEG have the same z-wave function and differ only in the x-y wave functions. This means that all electrons of the 2DEG are exposed to the quality of the walls at z=0 and z=L₇. However, this only limits the free mobility of the Nₑ^{leit}=D(E)·k·T electrons participating in the normal electric conduction, as they can be accelerated or scattered into free final states. For the Nₑ^{edel}=D(E)⋅(E_{F1z}−kT) noble electrons, these final states of possible disturbances are not available, so that they fulfill the conditions for a perfect free electron gas, which is therefore referred to as a 2-dimensional free electron gas (2DFEG).

Until now, the aim has been to improve the quality of the walls of a 2DFEG in order to increase the electric current Jₓ of the Nₑ^{leit} electrons in MOSFETs and HEMTs, for example. The current Jₓ=(Nₑ^{leit}/Lₓ·L_{y})·e·μ·Eₓ·L_{y} through a HEMT from the “source” electrode at x=0 to the “drain” electrode at x=Lₓ is proportional to μ. The electric field Eₓ=Uₓ/Lₓ with the voltage difference Uₓ between “source” and “drain”. In GaN-HEMTs, mobilities of μ=1·10³ to 2·10³ cm²/Vs are achieved at room temperature with electron surface densities of nₗₑᵢ=N^{leit}/(Lₓ·L_{y})≤2·10¹³ cm⁻² [5]. For the values Lₓ=5 mm, L_{y}=1 mm, Uₓ=5 V, μ=1000 cm²/Vs and nₗₑᵢₜ=1·10ₗₑᵢₜ¹³ cm⁻², this results in a current of Jₓ=1.6 mA, for example.

Ad b) All noble electrons of the conduction band with energies E<(E_{F1z}−kT) do not participate in normal electric conduction.

As shown above, by applying a magnetic field B_{z} in the z direction, it is possible to set the noble electrons into cyclotron motion in the x-y plane. If these noble electrons are exposed to an additional electric field E_{y} in the y-direction, they experience a cyclotron drift movement in the x-direction with the drift velocity v_{Dx}=E_{y}/B_{z}. The frequency and the drift velocity are independent of the energy of the electrons. All Nₑ^{edel}=D(E)−(E_{F1z}−kT) noble electrons therefore have the same drift velocity v_{Dx}. This allows the desired drift current density j_{Dx}=n_{edel}·e·V_{Dx} to be calculated. Assuming that the surface density of the noble electrons n_{edel}=N^{edel}/(Lₓ·L_{y}) is at least as large as nₗₑᵢₜ, this results in a drift current J_{Dx}=160 mA with U_{y}=10 V and B_{z}=1 Tesla, for example. As all the noble electrons involved are not subject to any perturbation, because all the final states of such perturbations are occupied, this drift current is loss-less and passes through the 2DFEG with the electric resistance Rₓₓ=0. It is therefore referred to from here as the super drift current J_{Dxsuper}. This J_{Dxsuper}=160 mA is an excellent result, but it has to be set in relation to the thermal loss of the current J_{y}=nₗₑᵢₜ·e·μ·E_{y}·Lₓ, which is necessary to generate the field E_{y} in the 2DFEG. With the example values used so far, J_{y}=80 mA with a thermal loss W_{y}=J_{y}·U_{y}=800 mW. This loss is too high and has to be reduced. The answer is provided by the ratio (J_{Dxsuper}/J_{y})=(n_{edel}/nₗₑᵢₜ)·(L_{y}/Lₓ)/(μ√B_{z}), which was previously equal to 2. Accordingly, (n_{edel}/nₗₑᵢₜ) jas to be made large and (μ·B_{z}) small.

The requirement for a small (μ·B_{z}) can easily be met for B_{z}, because a B_{z}=0.01 Tesla is easier to generate in the 2DFEG than B_{z}=1 Tesla. However, it is accepted that the minimum width L_{ymin} of the 2DEG has to be increased by a factor of 10. The requirement for small mobility u is completely contrary to all previous efforts, but is understandable, as the smallest possible current J_{y} is to be used here with the sole aim of producing the field E_{y}. In view of the development of HEMTs by modulation doping from MOSFETs in order to make u larger, a return to HEMT-2DEG structures but without modulation doping is an obvious way of reducing μ. This means that μ=200 cm²/Vs at T=300 K can be expected for the Nₑ^{leit} electrons, while the Nₑ^{edel} noble electrons are not affected. This has already been shown with a MOSFET in Ref. [6] with the first proof of Rₓₓ=0. However, in that experiment the temperature had to be cooled down to 1.5 K in order to reduce the width kT of the Fermi edge so that the QHE could be resolved. With these smaller example values μ=200 cm²/Vs and B_{z}=0.01 Tesla, a J_{Dxsuper}=16 A with U_{y}=10 V is achieved while the thermal loss is reduced to W_{y}=160 mW. Compared to the thermal loss of Wₓ=160 W of a hypothetical current of 16 A through a HEMT with Uₓ=10 V, this is an excellent result. This demonstrates the clear advantage of the invention over existing HEMTs. A further reduction of μ is possible by increasing the temperature to T>300 K, which, however, also slightly worsens the ratio n/n_{edelleit}.

Increasing n_{edel}/nₗₑᵢₜ is more complex, because the electron surface density n=nₗₑᵢₜ+n_{edel} is initially unknown, as only nₗₑᵢₜ is measured directly. In addition, in an asymmetric triangular QW, the energy states E_{mz} are closer and closer with increasing m (E_{2z}=1.67·E_{1z}, E_{3z}=2.34·E, E_{1z 24z}=2.88·E_{1z}, etc.). This leads to the occupation of several 2DFEG bands E_{F1z}, E_{F2} z, E_{F3z}, etc. with the same D(E). An analysis of this situation results. for example, for n=1·10ₗₑᵢₜ¹³ cm⁻² in the occupation of 5 2DFEG bands with E_{1z}=22.6 meV, E_{F1z}=65.2 meV and n_{edel}=0.885nₗₑᵢₜ. This corresponds with good approximation to the previous assumption of n_{edel}=nₗₑᵢₜ. The ratio n_{edel}/nₗₑᵢₜ can therefore hardly be improved with asymmetric triangular QW. This changes with symmetrical rectangular QWs, because in these QWs the energy states E_{pz}=E_{1z}·p² are further and further apart with increasing p, whereby E_{1z}=h²/(8·e·m*·L_{z}²)=1.88·10⁻¹⁸/L_{z}² [m]. With a semiconductor heterostructure with a symmetrical structure and, as an example, GaN as the QW material with a height of L_{z}=7 nm, nₗₑᵢₜ=1·10¹³ cm⁻² results in a single filled 2DFEG band with E_{F1z}=115.2 meV. Of these, 27 meV would be occupied by Nₗₑᵢₜ=nₗₑᵢₜ·Lₓ·L_{y} and 88.2 meV by N_{edel}=n_{edel}·Lₓ·L_{y}. This corresponds to a ratio n_{edel}/nₗₑᵢₜ=3.26. Under the simplifying assumption that n_{edel} remains n_{edel}=1·10¹³ cm⁻² as an example in this rectangular QW, nₗₑᵢₜ is reduced to nₗₑᵢₜ=3·10¹² cm⁻². With this value of nₗₑᵢₜ, W_{y} is reduced to W_{y}=48 mW for a loss-free current transport of J_{Dxsuper}=16 A. Compared to the thermal loss of the Wₓ=160 W of a hypothetical current Jₓ=16 A through a HEMT with Uₓ=10 V, this is an excellent result. This clearly demonstrates the advantage of the invention over existing HEMTs.

For practical application, the QWs of 2DEG heterostructures havz to be equipped with electrodes along Lₓ on both sides of the 2DEG at y=0 and y=L_{y}. According to the above discussion, these electrodes are needed to generate the electric field E_{y}=U_{y}/L_{y} in the 2DFEG with the voltage difference U_{y} between them.

In addition, the entire surface LₓxL_{y} has to be exposed to a magnetic field B_{z} in the z-direction. For this purpose, the entire heterostructure can be exposed to an external magnetic field B_{z}. However, internally produced magnetic fields with adaptation to the surface LₓxL_{y} are more suitable. This can be realized by permanent magnetic layers of size LₓxL_{y} of various types above or below or above and below the 2DFEG in the layered structure of the heterostructure. In this context, a 2DFEG in a symmetrical rectangular QW is advantageous because the heterostructure layers to be applied above and below the 2DFEG, including the permanent magnetic layers, can be made mirror-symmetrical.

A 2DFEG equipped in this way, which is arranged between the “source” electrode at x=0 and the “drain” electrode at x=Lₓ, can also be used directly as an almost loss-less transistor without a gate electrode. With a constant magnetic field B_{z}, the super current J_{Dxsuper} is only dependent on U_{y}, so that a perfectly linear current-voltage curve is obtained when controlled with U_{y}. For the above example with Lₓ=5 mm and L_{y}=1 mm, J_{Dxsuper}=1.6·U_{y} A with a thermal loss of only W_{y}=1.6U_{y}² mW. Since the cyclotron frequency at B=0.01 Tesla, for example, is equal to v=2.2−10⁹ s⁻¹, it can be assumed that the transistor allows switching frequencies of up to 1 GHz. These are all excellent prerequisites for the technical application of this new type of transistor, which deserves to be called a drift transistor.

By additionally attaching the usual gate electrodes as in HEMTs, the super current J_{Dxsuper} of a drift transistor can be controlled with a second, independent input signal U_{Gate}=U_{G}. The electron density n in the 2DFEG is changed non-linearly by U_{G}, which leads to a non-linear J_{Dxsuper}/U_{G} characteristic. An almost loss-less transistor with two independent control inputs U_{G} and U_{y} is a novelty that is becoming interesting for applications.

The almost loss-free super current can be increased by connecting drift transistors in parallel. The most effective method of increasing the current of a transistor in the micro range can be achieved by stacking q of the same QW in the z direction. Such structures are known as superlattices of QWs (see FIG. 10.34 in Ref. [1]). In addition to the semiconductor layers required to generate the QWs, an additional permanent magnet layer between the QWs is then sufficient to generate the magnetic field B_{z} in the entire superlattice. If the width L_{y}=1 mm is maintained, a supercurrent of J_{Dxsuper}=160 A with U_{y} and U_{G} can be controlled with q=10 parallel QWs in the superlattice. The loss of q QWs is then simply the loss of one QW multiplied by q.

While this invention has been described in terms of several advantageous embodiments, there are alterations, permutations, and equivalents, which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

### REFERENCES

[1] R. Gross and A. Marx, “Festkörperphysik”, Oldenbourg Verlag, 2012, ISBN 978-3-486-712294-0
[2] “High-electron-mobility transistor” in Wikipedia
[3] H.J. Andrä, “The Integer and Fractional Quantum Hall Effects and the transition between them”, DOI: 10.13140/RG.2.2.30277.32480 (2022)
[4] L. Landau, Z.Phys.64, 629 (1930)
[5] S. Guo et al.,Phys.Status Solidi A207, No.6, 1348 (2010), DOI: 10.1002/pssa.200983621
[6] K. v. Klitzing, G. Gorda, and M. Pepper, Phys.Rev.Lett. 45, 494 (1980)

1. Low-resistance to resistance-less electrical conductance at temperatures up to above room temperature, wherein a fraction of the electrons of high mobility μ>20 π/B_{z} m²/Vs located in the conduction band of a solid cannot be accelerated by an electric field and cannot be scattered by ions, defects, impurities or phonons, since all possible final states of these processes are occupied for these electrons, so that this fraction of electrons when exposed to crossed magnetic B_{z}-fields in the z-direction and electric E_{y}-fields in the y-direction provide a resistance-free cyclotron drift current in the x-direction, which reduces the overall electrical resistance of this solid.

2. Low-resistance to resistance-less electrical conductance of claim 1, wherein electrons of high mobility occupy all energy-states from the ground-state energy E₀ to the Fermi-Energie E_{F}>E₀ of the conduction band and are exposed to a magnetic field B_{z} in the z-direction and an electric field E_{y} in the y-direction which leads despite the energy between E₀ and E_{F}−kT of the electrons in the conduction band to a cyclotron-drift current of these electrons in the x-direction which is resistance-less since it is neither perturbed by thermal excitations of the electrons nor perturbed by scattering of the electrons on crystal-defects, on impurities, or on phonons, since all possible final states of these processes are occupied.

3. Low-resistance to resistance-less electrical conductance of claim 1, wherein solid-state structures are produced by MBE (Molecular Bearn Epitaxy) or similar methods that enable completely filled conduction bands of electrons with high mobility μ>200 π/B_{z}, with energies between E₀ and E_{F}, and with the property (E_{F}−E₀)>kT.

4. Low-resistance to resistance-less electrical conductance of claim 1, wherein solid-state structures or specifically semiconductor heterostructures with quantum wells are produced which enable the existance of 2DEG (two-dimensional electron gases) in the x-y plane with, for example, the length Lₓ and the width L_{y}, and with the properties specified in claim 1, whereby electrodes attached on both sides at ±L_{y}/2 and the voltage difference U_{y} between these two electrodes can generate the electric field E_{y} in the 2DEG.

5. Low-resistance to resistance-less electrical conductance of claim 1, wherein solid-state structures are produced by layering films of different materials so that different quantum well shapes for 2DEG can be produced or series of quantum wells for series of 2DEG in the three spatial directions become possible.

6. Low-resistance to resistance-less electrical conductance of claim 1, wherein the quantum well depth E_{F0}=E_{F}−E₀ is conditioned by various methods such as, for example, with the gate voltage of a HEMT, or with special doping concepts and/or with infrared radiation in such a way that E_{F0} is greater than kT at room temperature so that more than half of the electrons in the 2DEG can participate in the loss-less cyclotron drift current Jₓ.

7. Low-resistance to resistance-less electrical conductance of claim 1, wherein the 2DEG produced in the x-y plane are exposed to a not necessarily homogeneous magnetic field in the z-direction B, over the entire area LₓxL_{y} of the 2DEG, which is generated, for example, by external permanent magnets or by intrinsic magnetic structures adapted to the area LₓxL_{y} of the 2DEG, the latter comprising, for example, micro-permanent magnets, of permanent magnetic layers in the closest possible proximity to the 2DEG or of doping some of the layers defining the 2DEG with magnetizable nanoparticles (atoms) with which very high local magnetic fields B_{z} can be achieved.

8. Low-resistance to resistance-less electrical conductance of claim 1, wherein MOSFET (Metal Oxide Semiconductor Field Effect Transistor, see FIG. 10.36 in Ref. [5])-, or HEMT (High Electron Mobility Transistor, see FIG. 5.54 in Ref. [6]), or similar solid-state structures with 2DEG in the x-y plane comprising B_{z}-generation can be produced, in which the voltage U_{y}for the generation of the electric field E_{y}=U_{y}/L_{y} can be applied in the 2DEG over the width L_{y} of the 2DEG by corresponding electrodes, so that by action of the magnetic field in the z-direction B_{z} the supercurrent of all electrons of the 2DEG in the x-direction can be tapped at the “drain” electrode, which can be controlled with the gate voltage and/or with U_{y}.

9. Low-resistance to resistance-less electrical conductance of claim 1, wherein MOSFET-or HEMT-like solid-state structures are formed by several thin-film films (see FIG. 2b of Ref. [7] as an example) so that 2DEG comprising B_{z} generation with the greatest possible mobility μ of the electrons and E_{F0}>kT can be realized in supercurrent-conducting or supercurrent-producing microelectronic components, which can possibly be conditioned by infrared radiation.

10. Low-resistance to resistance-less electrical conductance of claim 1, wherein such microelectronic components, connected in series, provide a supercurrent conductor or, connected in parallel, a supercurrent generator.

11. Low-resistance to resistance-less electrical conductance of claim 1, wherein 2DEG with μ>20 π/B_{z}, E_{F0}<kT and B_{z}-generation, in large length L, are manufactured in an electronics component as voltage-controlled supercurrent conductors.

12. Low-resistance to resistance-less electrical conductance of claim 1, wherein integrated parallel circuits are manufactured of many 2DEG with μ>20 π/B_{z}, E_{F0}<kT and B_{z}-generation in one electronic component as a voltage-controlled super current generator.

13. Low-resistance to resistance-less electrical conductance of claim 1, wherein 2DEG microstructures with μ>20 π/B_{z}, E_{F0}<kT and B_{z}-generation are incorporated into integrated circuits, thereby significantly reducing their thermal losses.

14. Low-resistance to resistance-less electrical conductance of claim 1, wherein all electronic components mentioned so far are operated at lower temperatures than room temperature, which improves the condition E_{F0}>kT.
